(19) United States
(12) Patent Application Publication
(10) Pub. No.: US 2007/0113783 A1
(43) Pub. Date: May 24, 2007

(54) Band shield for substrate processing chamber

(75) Inventors: Wei Ti Lee, San Jose, CA (US); Steve Chiao, San Jose, CA (US)

Correspondence Address: JANAH & ASSOCIATES, P.C., 650 DELANCEY STREET, SUITE 106, SAN FRANCISCO, CA, 94107, US

(73) Assignee: Applied Materials, Inc.

(21) Appl. No.: 11/282,179

(22) Filed: Nov. 19, 2005

(51) Int. Cl. H01L 21/306; C23F 1/00

(52) U.S. Cl. 118/715; 156/916; 156/345.1; 156/345.31

(57) ABSTRACT

A band shield for a substrate processing chamber has a cylindrical wall with a slit therethrough. A flange extends radially outward from a bottom end of the cylindrical wall. A casing extends radially outwardly from a top end of the cylindrical wall and wraps around the slit to join to the flange. At least a portion of the surfaces of the cylindrical wall, flange, and casing have a surface roughness average of less than about 16 microinch, whereby less deposition occurs on these surfaces when they are exposed to the process environment in the substrate processing chamber. The vertical wall of the shield is absent any sills or other projections about the exhaust port to improve pumping conductance.

### BACKGROUND

The present invention relates to a band shield for a substrate processing chamber.

In the fabrication of electronic circuits and displays, semiconductor, dielectric, and electrically conductors are formed on a substrate, such as for example, a semiconductor wafer, ceramic or glass substrate. The materials are formed for example, by chemical vapor deposition (CVD), physical vapor deposition (PVD), ion implantation, oxidation or nitridation processes. Thereafter, the deposited substrate materials are etched to form features such as gates, vias, contact holes and interconnect lines. In a typical process, the substrate is placed on a support in a process zone of a chamber and exposed to heat or gas plasma to deposit or etch material on the substrate. The chamber has enclosing walls and is pumped down with pumps, such as roughing and turbo molecular pumps.

A band shield 20, as illustrated in FIG. 1, can also be used to protect the walls from erosion and also serve to receive process deposits from the process being conducted in the chamber. The band shield 20 is typically made from a ceramic material and is shaped to at least partially conform to the chamber walls. An exemplary prior art band shield 20 comprises a cylindrical sidewall 22 with a circumferential top flange 24 extending radially outward from the top end 26 of the sidewall 22 and a circumferential bottom flange 28 extending radially outward from the bottom end 30 of the sidewall 22. The top flange 24 couples to an outer shield (not shown) in the substrate processing chamber and the bottom flange 28 rests on a ledge. The band shield 20 includes a frontside 32 with a slit 34 and a backside 36 opposing the frontside. The top end 26 of the wall 22 has a first sill 38 that extends around the frontside 32 of the wall and a second sill 40 that extend around the backside 35 of the wall 22. The band shield 20 serves as a shield to receive process deposits, and thus, reduce the amount of process deposits formed on chamber walls.

However, in use, the conventional shield 20 has to be removed from the chamber and cleaned or replaced quite often. As process deposits accumulate on the sidewalls 22 and flanges 24, 28 of the shield 20, after a period of time, it has to be removed from the chamber and cleaned or replaced. For example, in the deposition of aluminum by CVD, the shield 20 has to be typically replaced or cleaned after processing of 3000 to 5000 substrates. It is desirable to have an shield 20 which can last for a greater number of process cycles before needing to be cleaned or replaced, to reduce the frequency of preventive maintenance cycles which are needed to operate the chamber.

Another problem of the shield 20 is that it restricts the pumping flow efficiency of the process chamber in which it is used. The chamber (not shown) typically has a pumping channel or port around the substrate which connected via a throttle valve to the external roughing and turbomolecular pumps. However, because the band shield 20 is positioned in the gas flow path between the substrate and the pumping channel or port, the flanges 24, 28 often block or otherwise impede the flow of gas out of the chamber and into the pumping channel. For example, when using the shield 20, the pressure in the chamber typically reaches about 5×10⁻⁵ Torr after about 10 seconds of pump down. It is desirable to have a band shield that allows more efficient pump down to reach lower chamber pressures in a faster time.

Thus it is desirable to have a band shield capable of limiting formation of process deposits on the walls of a substrate processing chamber. It is also desirable for the shield to be used for a greater number of process cycles without requiring replacement or cleaning. It is further desirable for the shield not to excessively impede the flow of gas through the pumping channel of the chamber.

### SUMMARY

A band shield for a substrate processing chamber has a cylindrical wall with a slit therethrough. A flange extends radially outward from a bottom end of the cylindrical wall. A casing extends radially outwardly from a top end of the cylindrical wall and wraps around the slit to join to the flange. At least a portion of the surfaces of the cylindrical wall, flange, and casing have a surface roughness average of less than about 16 micro inch, whereby less deposition occurs on these surfaces when they are exposed to the process environment in the substrate processing chamber.

A method of forming the band shield comprises forming a cylinder of a ceramic material and machining the cylinder to form the cylindrical wall with the slit, the flange extending radially outward from the bottom end of the cylindrical wall, and the casing extending radially outwardly from the top end of the cylindrical wall. The surfaces of the cylindrical wall, flange, and casing are polished to have the surface roughness average of less than about 16 micro inch.

### DRAWINGS

These features, aspects and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1 (PRIOR ART) is a perspective view of a prior art band shield for a substrate processing chamber;

FIG. 2A is a perspective view of an exemplary embodiment of a band shield according to the present invention;

FIG. 2B is a top plan view of the band shield of FIG. 2A;

FIG. 2C is a side elevation view of the band shield of FIG. 2A;

FIG. 2D is a front elevation view of the band shield of FIG. 2A;

FIG. 3 is a schematic sectional view of an exemplary embodiment of a processing apparatus comprising a chamber having the band shield; and

FIG. 4 is a schematic partial sectional view of an exemplary embodiment of a CVD plasma process chamber containing the band shield.

### DESCRIPTION

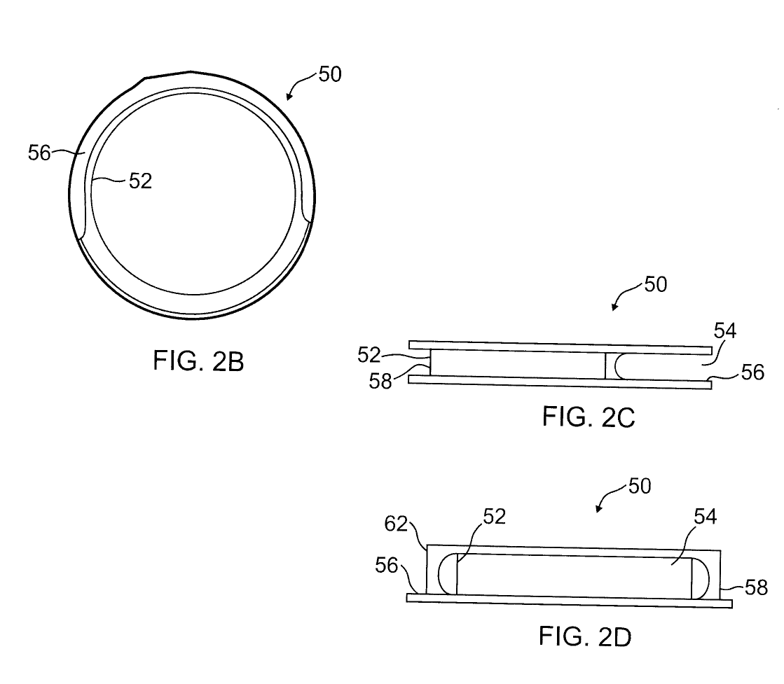

An exemplary embodiment of a band shield 50 suitable for a substrate processing chamber is illustrated in FIGS. 2A to 2D. The band shield 50 comprises a cylindrical wall 52 that is shaped and sized to surround the substrate held in the chamber. The cylindrical wall 52 is typically a right cylindrical shape that is substantially vertical or perpendicular to the plane of the substrate processed in the chamber and with a central axis of symmetry 53. However, the cylindrical wall 52 can also have a rectangular or square shaped cross-section to surround a substrate such as a display panel. While an exemplary version of the band shield 50 is illustrated, other versions that would be apparent to those of ordinary skill in the art are also within the scope of the present invention; thus, the present invention should not be limited to the illustrative embodiments described herein.

The cylindrical wall 52 has a midsection with a slit 54 that is typically an elongated oval hole having a diameter sized to pass a substrate, such as a circular semiconductor wafer, though the slit 54. In use, the slit 54 is positioned adjacent to a wafer loading slit 54 in the outer sidewall of the chamber so that a wafer can be passed from a transfer chamber through the slit 54 to rest on the substrate support in the chamber. For a wafer that is 300 mm in diameter, the width of the slit 54 is sized about 25% larger, for example, from about 360 to about 390 mm. The height of the slit is typically from about 30 to about 40 mm.

A flange 56 extends radially outward from a bottom end 58 of the cylindrical wall 52. The flange 56 is provided to support the band shield 50 in a process chamber. Generally, the flange 56 extends radially outward and substantially perpendicularly to the cylindrical wall 52. The flange 56 can also have notches 57 to align, secure, or serve as a pass-through in the chamber. Typically, the flange 56 extends around substantially the entire circumference of the cylindrical wall 52.

A casing 60 extends radially outwardly from a top end 62 of the cylindrical wall 52. The casing 60 wraps around the slit 54 in the midsection of the cylindrical wall 52 and is joined to at least a portion of the flange 56. The casing 60 is provided to enclose the slit 54 to surround the slit 54 from the surrounding chamber walls. The casing 60 is shaped as an oval frame that extends around the slit 54. The casing 60 comprises a top sill 62 and curved side walls 64 which are joined to a front frame 66, and closing the slit 54.

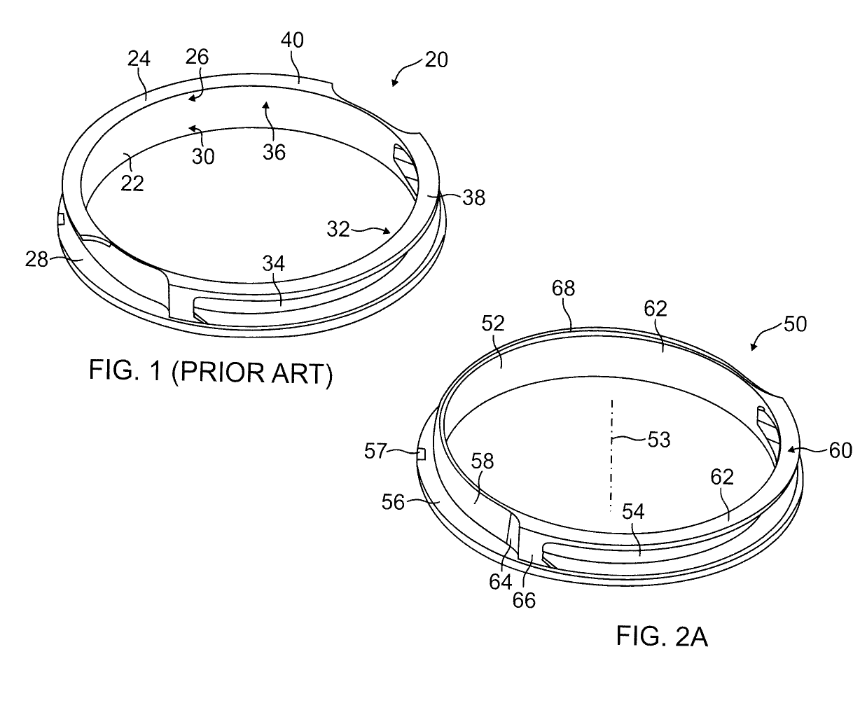

Prior art band shields 20, as shown in FIG. 1, included a second sill 40 that extended around the backside 36 of the cylindrical wall 22, opposing the frontside 32 with the slit 34. The second sill 40 was determined to be the cause of obstruction of the exhaust port and pump down system resulting in longer pump-down times for the chamber. Advantageously, the present band shield 50, as shown in FIG. 2A, is absent the second sill 40 about the exhaust port, and instead, in the band shield 50, the cylindrical wall 52 ends in a vertical wall 68. This provides significantly improved pump-down efficiency because the shield 50 lacks the obstruction of the second sill 40. Whereas chambers having the conventional shield 20 required 60 seconds to pump down to a vacuum level of 5×10⁻⁵ Torr, chambers that include the present version of the band shield 50 had pump-down times of about 10 seconds, to reach the same pressure. This was an unexpected result and significant improvement of 6 times better pump down efficiency which was surprising and unexpected.

At least a portion of the surfaces of the band shield 50, such as the cylindrical wall 52, flange 56, or casing 60, are exposed to the environment inside the chamber 100. Exposure to the process environment can include exposure to energized gases, such as plasma, formed in the chamber 100. The exposed surfaces can be treated to reduce their surface activity, and consequently, reduce process deposition on these surfaces. Such surface treatment can include polishing, sanding, bead blasting and the like. In one version, the exposed surfaces of the band shield 50 are treated to have predefined surface characteristics comprising a low surface roughness average. The surface roughness average is the mean of the absolute values of the displacements from the mean line of the peaks and valleys of the roughness features along the exposed surface. The roughness average can be determined by a profilometer that passes a needle over the surface to generate a trace of the fluctuations of the height of the asperities on the surface, by a scanning electron microscope that uses an electron beam reflected from the surface to generate an image of the surface, or by other surface measurement methods. For example, the band shield 50 can be cut into coupons and measurements made for each of the coupons to determine their surface characteristics. These measurements are then averaged to determine the surface roughness average. To measure properties of the surface such as roughness average, skewness, or other characteristics, the international standard ANSI/ASME B.46.1-1995 specifying appropriate cut-off lengths and evaluation lengths, can be used. In one version, the surface is treated to have a surface roughness average of less than about 50 microinch (˜1.3 micrometers; or even less that about 20 micronch (˜0.5 micrometers), or even less than about 16 microinch (˜0.4 micrometers). These surface roughness average limitations were found to significantly reduce process deposition on the shield surfaces when exposed to the process environment in the substrate processing chamber.

The band shield 50 is made from a dielectric material into the desired shape and then surface treated to achieve the desired surface roughness average levels. In one embodiment, the dielectric is made of a material that is permeable to RF energy, such as to be substantially transparent to RF energy from a plasma generator. For example, the dielectric may be a ceramic material, such as quartz or aluminum oxide. The shield 50 can be made by molding ceramic powder into the desired shape, for example, by cold isostatic pressing. In the cold isostatic pressing process, ceramic powder is combined with a liquid binding agent such as the organic binding agent polyvinyl alcohol. The mixture is placed in a rubber bag of an isostatic pressing device and a pressure is uniformly applied on the walls of the bag to compact the mixture to form a ceramic structure having the desired shape. The pressure can be applied, for example, by immersing the flexible container in water, and also by other methods of providing pressure. The molded ceramic preform can be made cylindrical or ring-like, using a hollow tube. The molded ceramic preform can be further shaped by machining the preform to provide the desired size. The shaped ceramic preform is then sintered to form a sintered ceramic. For example, aluminum oxide can be sintered at a temperature of from about 1300° C. to about 1800° C. in a duration of from about 48 to about 96 hours, typically at a pressure of about 1 atm. The sintered ceramic material can be further shaped, for example by at least one of machining, polishing, laser drilling, and other methods, to provide the desired ceramic structure.

The surface of the ceramic component is then bead blasted using beads comprising a grit of aluminum oxide having a mesh size selected to suitably grit blast the component surface, such as for example, a grit of aluminum oxide particles having a mesh size of 36. Grit blasting is used to roughen the surface. Thereafter, the surfaces are polished with a diamond pad to have a roughness average of less than about 16 microinches. This is much less than prior art shields which typically roughened to average surface roughness values of from about 150 microinches (˜3 micrometers) to about 450 microinches (˜18 micrometers). Lowering the surface roughness by a factor of greater than 4 was found to significantly and unexpectedly improve the life of the band shield. The resulting ceramic structure is cleaned to remove impurities and loose particles by blowing clean dry air or nitrogen gas across the surface, and then immersing the component in a solution of HNO₃ and/or HCl, then further cleaned by an ultrasonic rinse in distilled water. The component is then heated in an oven to bake out any residues from the cleaning process at a temperature of at least about 100° C.

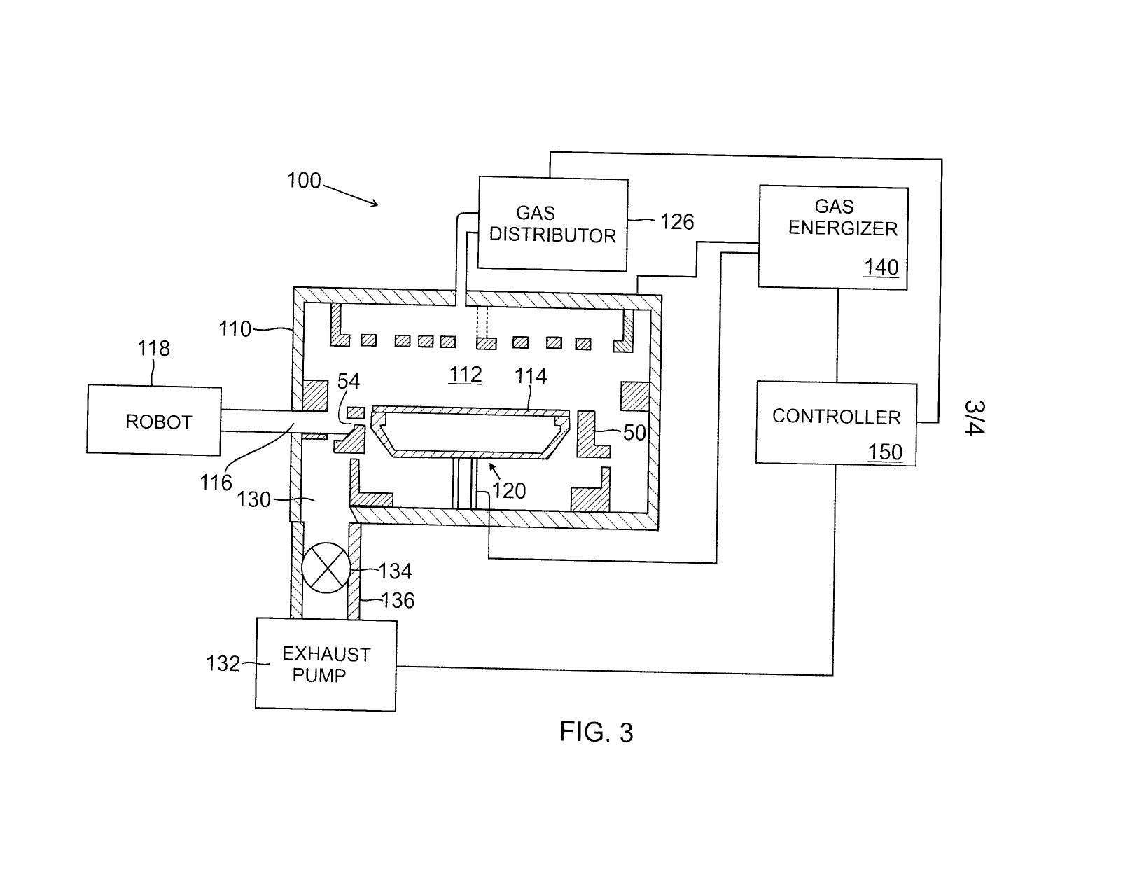

A band shield 50 according to the present invention may be used in a processing apparatus 100 having a chamber 110 that defines a process zone 112 capable of enclosing a substrate 114, an exemplary embodiment of which is shown in FIG. 3. The apparatus 100 can be, for example, a CVD chamber from Applied Materials, Inc., of Santa Clara, Calif. The apparatus 100 can be a stand-alone chamber or can be mounted on a platform, such as the ENDURA or CENTURA platform also from Applied Materials, to be part of a larger processing system that includes multiple chambers. The apparatus 100 can be adapted to deposit a metal and/or metal nitride layer by thermal or plasma enhanced CVD processes, including aluminum, cobalt, copper, molybdenum, niobium, titanium, tantalum, tungsten and some of their nitrides or other compounds.

A substrate support 120 in the process zone 112 of the chamber 110 supports a substrate 114 which is inserted into the chamber through a slit 116 by a robot 118 for processing. A gas distributor 126 provides precursor gases to the apparatus 100 which are energized in the chamber 110 to deposit a layer on the substrate 114. An annular pumping channel 128 around the substrate leads to an exhaust port 130 which is connected to an external exhaust pump 132 to evacuate the gases from the chamber 110. A throttle valve 134 along the conduit 136 and between the port 130 and the pump 132 is used to control the gas pressure in the chamber 110. A gas energizer 140 is provided to energize the process gas provided in the chamber 110. A controller 150 is used to control operation of the chamber components, such as the support 120, gas distributor 126, exhaust pumps 132, and gas energizer 140. The controller 150 comprises a general purpose computer with a CPU, such as a Pentium™ processor, Intel Corporation, Santa Clara, Calif., with appropriate program code written in a computer readable language, such as Pascal, and compiled appropriately.

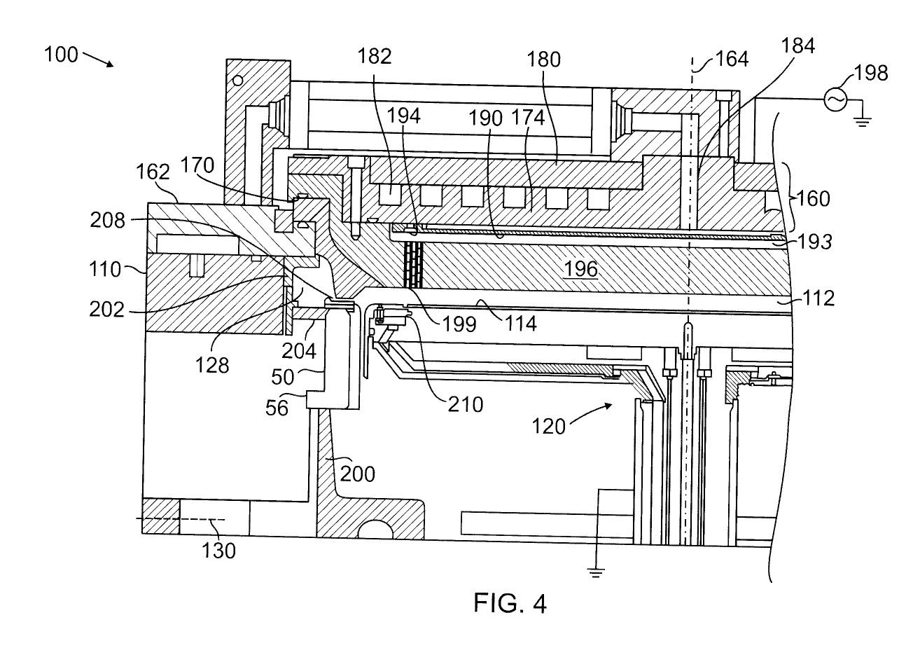

A more detailed view of an exemplary embodiment of a chamber 110 is provided in FIG. 4. The chamber 110 comprises a lid assembly 160 at an upper end of the chamber 110 having a radial axis 164 of symmetry. While the lid assembly 160 shown is substantially disc-shaped the invention is not limited to a particular shape, and parallelograms and other shapes are contemplated. The lid assembly 160 comprises a number of components stacked on top of one another including a lid rim 162, an isolator ring 170, and lower plate 174, and an upper plate 180. The upper plate 180 which in combination with the lower plate 174 defines channels 182 which allow heating or cooling of the lid assembly 160 when a fluid is passed therethrough, such as deionized water. The upper plate 180 (also known as a temperature control plate, gas-feed cover plate, backing plate or waterbox), is preferably made of aluminum or an aluminum alloy, and rests on the isolator ring 170 and acts to support the lid assembly 160. The plate 180 further includes a centrally located process gas inlet 184 adapted to deliver process gas to a showerhead 182. Although not shown, the process gas inlet 184 is coupled to one or more upstream gas sources and/or other gas delivery components, such as gas mixers, to form the gas distributor 126. A blocker plate 190, is preferably made of an aluminum alloy, and includes passageways 194 to disperse the gases flowing from the gas inlet 184 to a cavity 193 above a showerhead 196, from which it passes to the process zone 112 via plurality of holes 199 formed in the showerhead 196. The gas energizer 140 comprises a power supply 198 coupled to the lid assembly 160 to provide electrical power to the lid assembly to energize the process gas during substrate processing.

The band shield 50 surrounds the substrate 114 and is positioned in the chamber so that its flange 56 rests on a vertical inside wall 200 of the chamber 110. The slit 54 of the band shield 50 is sealable and is sized to allow a robot blade (not shown) to transfer substrates into and out of the apparatus 100. The band shield 50 is spaced from the substrate support 120.

The annular pumping channel 128 has sides generally defined by the band shield 50, liners 202, 204, and the isolator ring 170, with a choke aperture 208 being formed between the isolator ring 170 and the band shield 50. The isolator ring 170 comprises a monolithic ring-like structure manufactured of ceramic. The liner 202 is at the side of the pumping channel 160 facing the lid rim 162 and conforms to its shape. Both the liners 202 and 204 are maintained at an electrically floating potential during processing of a substrate 114. The liners 202, 204 are preferably made of metal, such as aluminum, and are bead blasted to increase the adhesion of any process deposits formed thereon, to reduce flaking of the deposited material which can otherwise result in contamination of the chamber 110. Optionally, the band shield 50, and the liners 202, 204 are assembled and sized as a process kit. The band shield 50 is annular having a diameter d1 and is disposed about the center of support 120. The liner 202 is also annular in the shape of a band extending axially along the centerline of the support 120 and with a diameter d2 greater than d1. The liner 204 is also annular and forms a ring-shape about the substrate 114.

In use, the support 120 is moved to a lowered receiving position, and the robot 118 with a substrate 114 thereon is moved through the outer slit 116 in the chamber wall, through the annular slit 54 in the band shield 56, and to a position directly above the support 120. The substrate is then held by the prongs 210 of the support 120 and the robot 118 is retracted from the apparatus 100. Process gas is then supplied to the lid assembly 160 by the gas distributor 126, and the gas enters the process gas inlet 184 to be distributed into the chamber through the passageways 194 in the blocker plate 190 and then through the plurality of holes 199 formed in the showerhead 196 where it is delivered to the process zone 112.

Upon delivery to the process zone 112, the gas contacts the substrate 114 which is maintained at an elevated temperature corresponding to the disassociation temperature of the process gas, for example, between about 100° C. and about 450° C., or even from about 250° C. to about 450° C. The substrate 114 is heated by the support 120 which has a heater, such as resistance heating elements in the support 120. The process gas is introduced into the chamber 110 and typically maintained at a pressure of from about 100 mTorr to about 20 Torr. Thereby, a metal and/or metal nitride layer is conformally deposited on the substrate 114 via a CVD process. The disassociation process is a thermal process not usually relying upon plasma excitation of the precursor gas; however, a plasma can also be formed during the deposition process or post deposition to remove impurities by applying power to the RF source 130 to form a plasma from the process gas. Unreacted gas and gaseous byproducts are then exhausted from the apparatus 100 under the influence of the negative pressure provided by a vacuum pump 255. Accordingly, the gas flows through the choke aperture 208 over the top wall 68 of the shield 50 into the pumping channel 160.

A band shield 50 having a surface finish and shape according to the present invention provides significant advantages over conventional band shields 20. For example, the band shield 50 reduces the deposition of precursor gases and vapors sputtered material onto the shield surfaces. Thus, the band shield 50 exhibits longer operational lifetimes between cleaning cycles than a conventional shield 20. The lifetime of the band shield 50 is prolonged because the band shield 50 accumulates much less deposits on its surfaces, and thus, does not have to be removed or cleaned as often as the conventional shield 20. Furthermore, the present band shield 50 has a vertical wall 68 without a sill extending from the wall as in the prior art shield 20, provides substantially improved pump-down time over the prior art shield 20. This occurs because removal of the blockage caused by the sill of prior art designs, increases in chamber pumping conductance and thereby, improves pump down performance.

While the present invention has been described in considerable detail with reference to certain preferred versions, many other versions should be apparent to those of ordinary skill in the art. For example, other shapes and configurations of the shield 50 should be apparent to those of ordinary skill in the art. In addition, the shield 50 may be used in other types of chambers, such as for example, PVD, ion implantation, RTD or other chambers. Therefore, the spirit and scope of the appended claims should not be limited to the description of the preferred versions contained herein.

What is claimed is:

1. A band shield for a substrate processing chamber, the band shield comprising:
(a) a cylindrical wall having a slit, and top and bottom ends;
(b) a flange extending radially outward from the bottom end of the cylindrical wall;
(c) a casing extending radially outwardly from the top end of the cylindrical wall, the casing wrapping around the slit to join to the flange, and
wherein at least a portion of the surfaces of the cylindrical wall, flange, and casing have a surface roughness average of less than about 16 microinch, whereby less deposition occurs on these surfaces when exposed to the process environment in the substrate processing chamber.

2. A band shield according to claim 1 wherein the casing extends around substantially only the slit.

3. A band shield according to claim 1 wherein at least 50% of the circumference of the top end of cylindrical wall terminates substantially vertically.

4. A band shield according to claim 1 wherein the top end of the cylindrical wall about the casing is absent a radially extending flange.

5. A band shield according to claim 1 comprising a dielectric material.

6. A band shield according to claim 5 wherein the dielectric material comprises aluminum oxide.

7. A substrate processing chamber comprising the band shield according to claim 1, the chamber further comprising:
(a) an outer sidewall having a ledge that extends radially inward so that the band shield when placed on the ledge substantially covers up the outer sidewall to reduce deposition on the outer sidewall during processing conducted in the chamber;
(b) a substrate support;
(c) a gas distributor;
(d) a gas energizer; and
(e) a pumping channel,
whereby a substrate received on the support may be processed by gas introduced through the gas distributor, energized by the gas energizer, and exhausted through the pumping channel.

8. A band shield for a substrate processing chamber, the band shield composed of aluminum oxide and comprising:
(a) a cylindrical wall having a slit therethrough, the cylindrical wall having top and bottom ends, at least 50% of a circumference of the top end terminating substantially vertically;
(b) a flange extending radially outward from the bottom end of the cylindrical wall;
(c) a casing extending radially outwardly from the top end of the cylindrical wall, the casing wrapping around substantially only the slit to join to the flange, and
wherein at least a portion of the surfaces of the cylindrical wall, flange, and casing have a surface roughness average of less than about 16 microinch, whereby less deposition occurs on these surfaces when exposed to the process environment in the substrate processing chamber.

9. A band shield according to claim 8 wherein the top end of the cylindrical wall about the casing is absent a radially extending flange.

10. A method of forming a band shield for a substrate processing chamber, the method comprising:
(a) forming a cylinder of a ceramic material;
(b) machining the cylinder to form
(i) a cylindrical wall having a slit therethrough, the cylindrical wall having top and bottom ends;
(ii) a flange extending radially outward from the bottom end of the cylindrical wall; and
(ii) a casing extending radially outwardly from the top end of the cylindrical wall, the casing wrapping around the slit to join to the flange; and
(c) polishing the surfaces of the cylindrical wall, flange, and casing to have a surface roughness average of less than about 16 microinch, whereby less deposition occurs on the polished surfaces when exposed to the process environment in the substrate processing chamber.

11. A method according to claim 10 comprising machining the cylinder to form a casing that extends substantially only around the slit.

12. A method according to claim 10 comprising machining the cylinder to form a cylindrical wall having a top end with a circumference, wherein at least 50% of the circumference of the top end terminating substantially vertically.

13. A method according to claim 10 comprising machining the cylinder to form a cylindrical wall having a top end that is substantially absent a radially extending flange.

14. A method according to claim 10 comprising machining the cylinder from a ceramic material comprising aluminum oxide.
